(19) United States
(12) Patent Application Publication
(10) Pub. No.: US 2008/0272481 A1
(43) Pub. Date: Nov. 6, 2008

(54) Pin grid array package substrate including slotted pins

(76) Inventors: Rajendra Dias, Phoenix, AZ (US); Xinyan Zhao, Phoenix, AZ (US)

Correspondence Address: INTEL CORPORATION;c/o INTELLEVATE, LLC, P.O. BOX 52050, MINNEAPOLIS, MN, 55402, US

(21) Appl. No.: 11/800,223

(22) Filed: May 4, 2007

(51) Int. Cl. H01L 23/48

(52) U.S. Cl. 257/697; 257/E23.068

(57) ABSTRACT

An electrically conductive pin comprising a pin stem and a pin head attached to the pin stem. The pin head is adapted to be mounted onto a surface of a microelectronic substrate to support the pin stem. The pin head defines at least one slot therein, the at least one slot being configured to allow gases to escape therethrough from a region at an underside of the pin head.

### FIELD

Embodiments of the present invention relate generally to pin grid array package substrate configurations.

### BACKGROUND

Pin grid array (PGA) packages are well known in the art. During flip chip attach of a microelectronic die to a substrate including a PGA thereon, a reflow process typically occurs at high temperatures, such as, for example, at about 250 degrees Celsius to join solder bumps on the PGA substrate to conductive bumps, typically Cu bumps, on the die. The reflow process softens and melts not only the solder bumps on the PGA substrate, but also the solder, such as SnSb (sometimes alloyed with Au from the substrate lands), that is typically used to attach the pins of the PGA to lands on the package substrate (hereinafter “pin-attach solder”). In addition to a softening of the pin-attach solder reflow of the solder bumps on the PGA substrate volatile material trapped in the pin-attach solder tends to vaporize and, along with any air voids trapped in the pin-attach solder, try to escape from the same. A softening of the pin-attach solder and movement of the vaporized volatile material and air voids therein during reflow contribute to lift and pin and cause a tilting of the pins supported by the pin-attach solder. The above problem is exacerbated as pins are getting smaller and therefore lighter, and as pin count/pin density increases.

The prior art attempts to address the problem of pin tilt include reducing the reflow temperature in order to control a softening of the pin-attach solder and a movement of vaporized volatile material therein. Doing so has shown to improve pin tilt yields, but, disadvantageously, increases the risk for non wets/de-wets on the die to substrate interconnection.

The prior art fails to provide an effective method of minimizing pin tilt during flip chip attach of a die to a PGA substrate.

### BRIEF DESCRIPTION OF THE DRAWINGS

FIG. 1 is a schematic, side-cross sectional view of a microelectronic package according to embodiments;

FIG. 2 is a schematic side view of a conductive pin according to an embodiment;

FIGS. 3-6 are schematic top plan views of the pin of FIG. 2 according to four respective embodiments; and

FIG. 7 is a schematic view of an embodiment of a system incorporating a microelectronic package as shown in FIG. 1.

For simplicity and clarity of illustration, elements in the drawings have not necessarily been drawn to scale. For example, the dimensions of some of the elements may be exaggerated relative to other elements for clarity. Where considered appropriate, reference numerals have been repeated among the drawings to indicate corresponding or analogous elements.

### DETAILED DESCRIPTION

In the following detailed description, a microelectronic package, a solder alloy used to form the package, a method to make the solder alloy, and a system including the package are disclosed. Reference is made to the accompanying drawings within which are shown, by way of illustration, specific embodiments by which the present invention may be practiced. It is to be understood that other embodiments may exist and that other structural changes may be made without departing from the scope and spirit of the present invention.

The terms on, above, below, and adjacent as used herein refer to the position of one element relative to other elements. As such, a first element disposed on, above, or below a second element may be directly in contact with the second element or it may include one or more intervening elements. In addition, a first element disposed next to or adjacent a second element may be directly in contact with the second element or it may include one or more intervening elements. In addition, in the instant description, figures and/or elements may be referred to in the alternative. In such a case, for example where the description refers to Figs. X/Y showing an element A/B, what is meant is that Fig. X shows element A and Fig. Y shows element B. In addition, a “layer” as used herein may refer to a layer made of a single material, a layer made of a mixture of different components, a layer made of various sub-layers, each sub-layer also having the same definition of layer as set forth above.

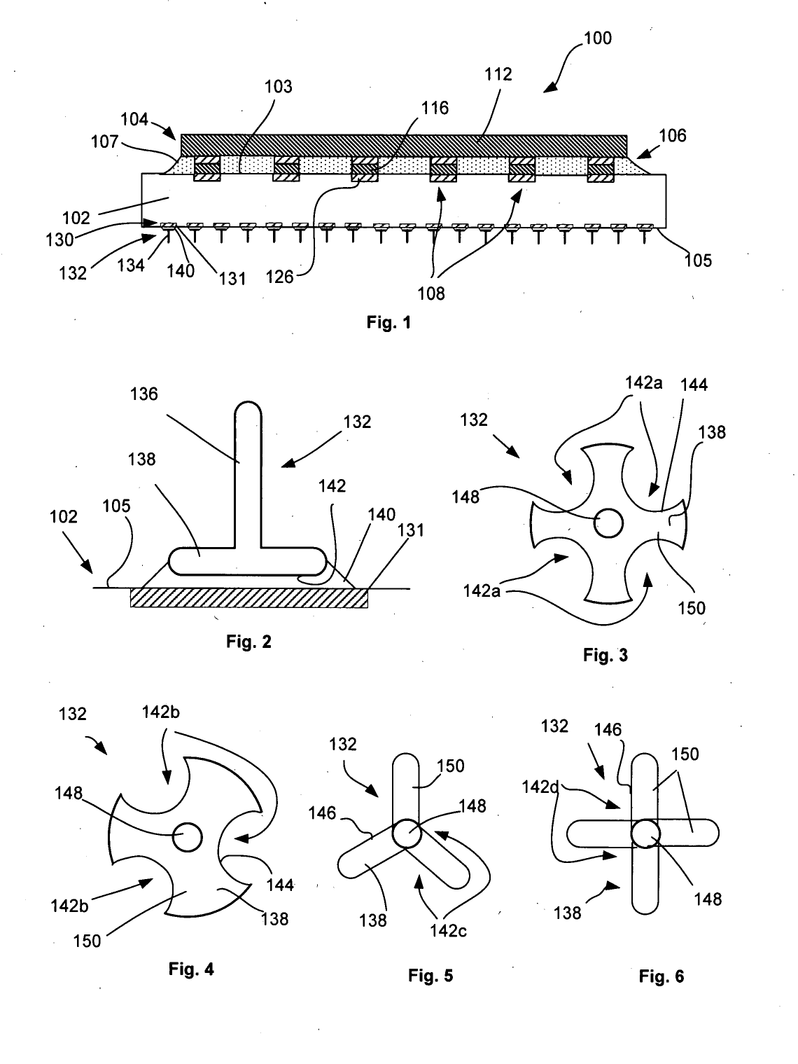

Aspects of this and other embodiments will be discussed herein with respect to FIGS. 1-7 below. The figures, however, should not be taken to be limiting, as it is intended for the purpose of explanation and understanding.

Referring first to FIG. 1, a microelectronic package 100 is shown according to one embodiment. Package 100 includes a package substrate 102, and a die 104 bonded to the substrate by a bond 106. The substrate 102 includes a die-side surface 103 which is adapted to receive die 104 thereon, such as by including under-bump metallization or UBM in the form of lands 126. The substrate 102 further includes a PCB-side surface 105 adapted to electrically and mechanically couple the package 100 to a printed circuit board or PCB in a well known manner. As seen in FIG. 1, a plurality of joint structures 108 are shown between the die 104 and the substrate 102, the joint structures 108 forming at least part of bond 106. Optionally, the bond 106 may also include an underfill material 107 provided in a well known manner. Substrate 102 further includes an array 130 of land pads 131 on the PCB-side surface 105 of substrate 102. By “land pad,” what is meant in the context of the instant application is a site on a substrate, such as a package substrate, adapted to allow an electrical and mechanical joining of the substrate With another microelectronic component, such as through a solder connection or through a PGA. The substrate 102 as shown includes a PGA substrate, and thus comprises an array 132 of electrically conductive pins 134 electrically and mechanically bonded to respective ones of the land pads 131.

Referring next to FIG. 2, a side view is shown of one of the pins 134 of FIG. 1 in a state where the pin 134 is shown as being mounted onto substrate 102. According to embodiments, as shown by way of example in FIG. 2, a pin 134 of the array 132 (FIG. 1) includes a pin stem 136 and a pin head 138 attached to the pin stem. In the shown embodiment, the pin stem 136 extends in a substantially perpendicular direction with respect to the pin head 138. Each pin head 138 is shown as being mounted onto a corresponding land pad 131 of the array 130 onto the PCB-side surface 105 of substrate 102 using a pin-attach solder joint 140 as shown. As seen in FIG. 2, the pin-attach solder joint 140 electrically and mechanically bonds an underside 142 of pin head 138 to the PCB-side surface 105.

Referring next to FIGS. 3-6, top plan views of the pin 134 of FIG. 2 are shown depicting various embodiments of a pin. As suggested in FIGS. 3-6, according to embodiments, a pin head defines one or more slots therein. By “slot,” what is meant in the context of embodiments is a discontinuity in the pin head extending from the underside thereof at least partially through a thickness of the pin head, and configured to allow gases to escape therethrough from a region at an underside of the pin head. FIGS. 3, 4, 5 and 6 respectively show slots 142a, 142b, 142c and 142d according to respective embodiments. In the shown embodiments, the slots extend through a thickness of the pin heads 138. As seen in FIGS. 3, and 4, the slots may present curved boundaries 144. As seen in FIGS. 5 and 6, the slots may present angular boundaries 146. In the shown embodiments of FIGS. 3-6, the pin head 138 has a pin stem base region 148, and a plurality of arms 150 extending away from the pin stem base region 148 substantially perpendicular to the pin stem 136. The arms 150 may have straight side surfaces as shown in FIGS. 5 and 6, or curved side surfaces as shown in FIGS. 3 and 4. Any number of slots may be provided on a given pin head according to embodiments, ranging from one slot to multiple slots. Preferably, a pin head includes four slots distributed symmetrically with respect to the pin stem to promote stability of the pin. Embodiments are not limited to through-slots, however, and include within their scope slots that extend only partially through a thickness of a pin head, in this way forming a space between the undersurface of the pin head and the pin-attach solder joint 140. Although only four different configurations/embodiments of a slotted pin are shown respectively in FIGS. 3-6, embodiments are not so limited, and include within their scope multiple variations on a design of each slot. For example, according to one embodiment, the slots comprise through-holes (not shown) defined in the pin head. In addition, the pin head may be provided according to any well known method, for example, by way of cold forming, and the slots may be provided according to any well known method, such as, for example, through punching, stamping, machining, laser cutting, etc. Where the slots comprise through-holes, such slots may be provided by way of laser drilling or machining.

Advantageously, the provision of slots, such as, for example, slots 142a-142d shown in FIGS. 3-6, in the pin head of conductive pins of PGA substrates, allows solder voids and flux volatiles to escape during high temperature reflow processes to attach a die to the package substrate, and in this way substantially prevent pin tilt. Additionally, advantageously, the slots allow increased surface area for the pin-attach solder to wet the pin, and in this way allow for the formation of a robust pin-attach solder joint. Moreover, the slots advantageously allow for volatiles and trapped air voids to escape from an underside of the pin during pin attach to substrate lands, in this way bringing about a pin-attach solder joint including fewer voids under the pin and hence improved pin pull strength performance. Furthermore, the slots advantageously allow any volatiles and/or trapped voids still under the pin head to escape during reflow/die attach without causing the pin to tilt.

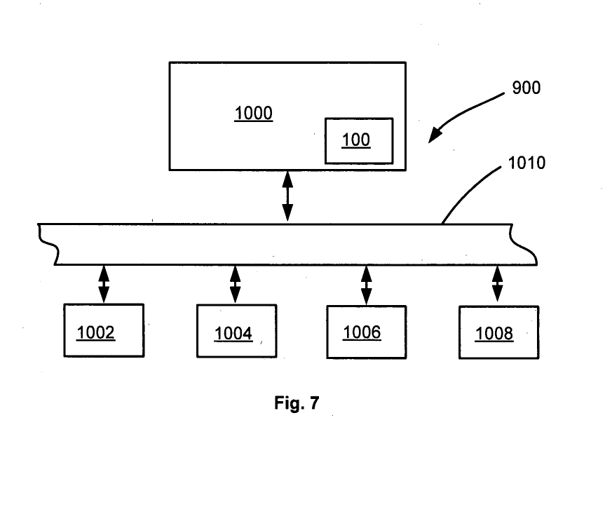

Referring to FIG. 7, there is illustrated one of many possible systems 900 in which embodiments of the present invention may be used. In one embodiment, the electronic assembly 1000 may include a microelectronic package, such as package 100 of FIG. 1. Assembly 1000 may further include a microprocessor. In an alternate embodiment, the electronic assembly 1000 may include an application specific IC (ASIC). Integrated circuits found in chipsets (e.g., graphics, sound, and control chipsets) may also be packaged in accordance with embodiments of this invention.

For the embodiment depicted by FIG. 7, the system 900 may also include a main memory 1002, a graphics processor 1004, a mass storage device 1006, and/or an input/output module 1008 coupled to each other by way of a bus 1010, as shown. Examples of the memory 1002 include but are not limited to static random access memory (SRAM) and dynamic random access memory (DRAM). Examples of the mass storage device 1006 include but are not limited to a hard disk drive, a compact disk drive (CD), a digital versatile disk drive (DVD), and so forth. Examples of the input/output module 1008 include but are not limited to a keyboard, cursor control arrangements, a display, a network interface, and so forth. Examples of the bus 1010 include but are not limited to a peripheral control interface (PCI) bus, and Industry Standard Architecture (ISA) bus, and so forth. In various embodiments, the system 90 may be a wireless mobile phone, a personal digital assistant, a pocket PC, a tablet PC, a notebook PC, a desktop computer, a set-top box, a media-center PC, a DVD player, and a server.

The various embodiments described above have been presented by way of example and not by way of limitation. Having thus described in detail embodiments of the present invention, it is understood that the invention defined by the appended claims is not to be limited by particular details set forth in the above description, as many variations thereof are possible without departing from the spirit or scope thereof.

What is claimed is:

1. A microelectronic package substrate comprising:
a die-side surface adapted to receive a die thereon;
a PCB-side surface adapted to be mechanically and electrically bonded to a PCB;
an array of land pads on the PCB-side surface;
an array of electrically conductive pins electrically and mechanically bonded to respective ones of the land pads, each of the pins having a pin stem and a pin head attached to the pin stem, the pin head being mounted onto a corresponding land pad, at least some pin heads defining slots therein, the slots being configured to allow gases to escape therethrough from a region at an underside of a corresponding one of said at least some pin heads; and
a plurality of pin-attach solder joints mechanically and electrically bonding the pins to corresponding ones of the land pads.

2. The substrate of claim 1, wherein at least some the slots extend through a thickness of said at least some pin heads.

3. The substrate of claim 1, wherein at least some of the slots extend only partially through a thickness of said at least some pin heads.

4. The substrate of claim 1, wherein at least some of the slots have one of curved boundaries and angular boundaries.

5. The substrate of claim 1, wherein the slots include at least three slots.

6. The substrate of claim 1, wherein each of said at least some pin heads includes a pin stem base region, and a plurality of arms extending away from the pin stem base region substantially perpendicular to the pin stem.

7. The substrate of claim 6, wherein said plurality of arms have straight side surfaces.

8. The substrate of claim 6, wherein said plurality of arms have curved side surfaces.

9. An electrically conductive pin comprising:
a pin stem; and
a pin head attached to the pin stem, the pin head being adapted to be mounted onto a surface of a microelectronic substrate to support the pin stem, the pin head defining at least one slot therein, the at least one slot being configured to allow gases to escape therethrough from a region at an underside of the pin head.

10. The pin of claim 9, wherein at least some the slots extend through a thickness of said at least some pin heads.

11. The pin of claim 9, wherein at least some of the slots extend only partially through a thickness of said at least some pin heads.

12. The pin of claim 9, wherein at least some of the slots have one of curved boundaries and angular boundaries.

13. The pin of claim 9, wherein the slots include at least three slots.

14. The pin of claim 9, wherein each of said at least some pin heads includes a pin stem base region, and a plurality of arms extending away from the pin stem base region substantially perpendicular to the pin stem.

15. The pin of claim 6, wherein said each of the plurality of arms has one of straight side surfaces and curved side surfaces.
